(19) United States
(12) Patent Application Publication
(10) Pub. No.: US 2026/0269201 A1
(43) Pub. Date: Sep. 10, 2026

(54) ANALYSIS APPARATUS, ANALYSIS METHOD, ANALYSIS PROGRAM, AND PLASMA PROCESSING METHOD

(71) Applicant: HORIBA STEC, Co., Ltd., Kyoto (JP)

(72) Inventors: Yoko SATO, Kyoto (JP); Daisuke HAYASHI, Kyoto (JP)

(73) Assignee: HORIBA STEC, Co., Ltd., Kyoto (JP)

(21) Appl. No.: 19/553,899

(22) Filed: Mar. 2, 2026

(30) Foreign Application Priority Data
Mar. 6, 2025 (JP) 2025-035108
Dec. 11, 2025 (JP) 2025-245674

(51) Int. Cl. H01J 37/32; G01N 21/71

(52) U.S. Cl. CPC H01J 37/32972; G01N 21/718; G01N 2201/08

(57) ABSTRACT

An analysis apparatus includes: an emission detection unit that detects, for each wavelength, emission intensities of the plasma at measurement positions different from each other in a plane of a substrate; a classification unit that classifies data sets formed with the emission intensities at the respective measurement positions at each wavelength into a plurality of data aggregates at a plurality of wavelengths; and a representative data output unit that outputs representative data indicating distribution of the chemical species in the plane of the substrate, on the basis of the plurality of data aggregates.

### CROSS-REFERENCE TO RELATED APPLICATION

The present application claims priority of Japanese Applications 2025-035108, filed on Mar. 6, 2025, and 2025-245674 filed on Dec. 11, 2025, the entire contents of which are hereby incorporated by reference in their entireties.

### BACKGROUND OF THE INVENTION

### 1. Technical Field

The present invention relates to an analysis apparatus, an analysis method, an analysis program, and a plasma processing method.

### 2. Description of the Related Art

In a conventional substrate processing process in a semiconductor manufacturing process, plasma is generated in a processing chamber accommodating a substrate such as a wafer, and processing such as etching is performed on the substrate. In this substrate processing process, to detect an end point and analyze the chemical species in the processing chamber, for example, a plasma emission monitor (an optical emission spectrometer; OES) that detects plasma emission in the processing chamber is used, as disclosed in JP 2010-219263 A, for example.

### PRIOR ART DOCUMENT

### Patent Document

JP 2010-219263 A

### SUMMARY OF THE INVENTION

Meanwhile, a conventional plasma emission monitor placed above a surface of the substrate detects only light emission from the central portion of the substrate, and therefore, the distribution of the chemical species at the central portion of the substrate is mainly analyzed.

In the substrate processing process, however, there is a possibility that the processing state of the substrate is different between the central portion and a peripheral portion of the substrate. Because of this, the distribution of the chemical species above the surface of the substrate cannot be analyzed with the conventional plasma emission monitor.

Therefore, the present invention has been made in view of the above problem, and a main object thereof is to analyze the distribution of a chemical species above a surface of the substrate to be processed with plasma.

Specifically, an analysis apparatus according to the present invention is an analysis apparatus that analyzes a chemical species generated by processing of a substrate with plasma in a processing chamber, and includes: an emission detection unit that detects, for each wavelength, emission intensities at measurement positions different from each other above a surface of the substrate; a classification unit that classifies data set elements formed with the emission intensities at the respective measurement positions at each wavelength into a plurality of data aggregates at a plurality of wavelengths; and a representative data output unit that outputs representative data indicating distribution of the chemical species in a plane of the substrate, on the basis of the plurality of data aggregates.

In such an analysis apparatus, the emission detection unit detects emission at measurement positions different from each other, and thus, it is possible to detect emission intensities for each wavelength above the surface of the substrate. Accordingly, the classification unit classifies the data set elements at a plurality of wavelengths into a plurality of data aggregates, so that the distribution of the chemical species in the plane of the substrate can be checked on the basis of the plurality of data aggregates.

On the other hand, in a conventional analysis apparatus, the amount of information is enormous when analysis is performed for all the wavelengths detected by a plasma emission monitor. Therefore, the conventional analysis apparatus extracts some of the wavelengths of the emission intensities at the respective wavelengths detected by the plasma emission monitor, and analyzes the emission intensities at the extracted wavelengths. However, the extraction of the wavelengths requires construction of a database, or greatly depends on the experience of the user.

In the analysis apparatus according to the present invention, on the other hand, the classification unit classifies the data set elements formed with emission intensities at the respective positions above the surface of the substrate into a plurality of data aggregates at a plurality of wavelengths. Thus, all the emission spectrum information detected by the emission detection unit is reflected in the plurality of data aggregates after the classification. Therefore, there is no need to extract the emission intensities at some of the wavelengths from the emission intensities at the respective wavelengths as detected by the emission detection unit, and thus, it is possible to analyze the distribution of the chemical species above the surface of the substrate, regardless of the database and/or the ability of the user.

The data aggregates are different from each other in a waveform pattern formed with the emission intensities of the plasma at the respective measurement positions, and the representative data output unit calculates the representative data on the basis of two or more of the data aggregates different from each other.

With this configuration, the representative data is calculated on the basis of two or more data aggregates having different waveform patterns from each other for a plurality of measurement positions, and thus, it is possible to accurately analyze the distribution of the chemical species above the surface of the substrate, compared with that in a case where the representative data is calculated with one data aggregate.

Two of the data aggregates each have a representative emission intensity that is a plasma emission intensity representing each corresponding data aggregate, and the representative data is the ratio between the representative emission intensities in the two of the data aggregates.

In this configuration, the representative data is the ratio between the representative emission intensity in two data aggregates, and accordingly, changes in the emission intensities at the respective measurement positions are clearer in the representative data. As a result, the distribution of the chemical species in an in-plane direction of the substrate can be more accurately analyzed on the basis of the representative data.

The representative data output unit outputs the representative data, on the basis of a data aggregate in which the emission intensity of the plasma at the central portion of the substrate is maximum, and a data aggregate in which the emission intensity of the plasma at the central portion of the substrate is minimum.

In this configuration, the representative data output unit outputs the representative data, on the basis of a data aggregate in which the emission intensity at the central portion of the substrate is maximized, and a data aggregate in which the emission intensity at the central portion of the substrate is minimized. Accordingly, the representative data is calculated on the basis of two data aggregates that have characteristic changes in the emission intensities in an in-plane direction. As a result, in the representative data, the changes in the emission intensities at the respective positions are more clearly shown, and thus, the distribution of the chemical species ratio above the surface of the substrate can be more accurately analyzed on the basis of the representative data.

Here, in a case where the data aggregate in which the emission intensity at the central portion of the substrate is maximum represents one of a data aggregate indicating a chemical species contributing to a reaction, such as an etchant, for example, and a data aggregate indicating a behavior opposite to that of a chemical species contributing to a reaction, such as a by-product, for example, the data aggregate in which the emission intensity at the central portion of the substrate is minimum indicates the other one of the data aggregates. Accordingly, on the basis of the data aggregate in which the emission intensity is maximum the central portion of the substrate, and the data aggregate in which the emission intensity is minimum at the central portion of the substrate, it is possible to analyze the distribution of the ratio between the two chemical species exhibiting opposite behaviors above the surface of the substrate, such as an etchant and a by-product, for example.

An emission intensity standardization unit that standardizes emission intensities of the plasma at the respective wavelengths for each of the measurement positions is further included, and the classification unit classifies the data set elements at a plurality of wavelengths, using the standardized emission intensities of the plasma.

With this configuration, the emission intensity standardization unit standardizes emission intensities at measurement positions different from each other, and thus, the difference in the emission intensity at each measurement position can be made uniform. As a result, the classification unit can accurately classify the data set elements at a plurality of wavelengths, using the standardized emission intensities.

The emission detection unit includes: a plurality of light guide units, each of which is formed with one or a plurality of fibers, the light guide units guiding emission of the plasma at positions different from each other in an in-plane direction of the substrate via the fibers; and a detection unit that detects the emission intensities corresponding to the emission of the plasma guided by the light guide units for each wavelength. The number of the fibers in at least one of the light guide units is different from the number of the fibers in each of the other ones of the light guide units.

In this configuration, the number of fibers in at least one light guide unit among the light guide units is different from the number of fibers in each of the other light guide units, the emission detection unit can detect a plurality of different emission intensities with high sensitivity. As a result, even in a case where the emission intensities are different between the central portion and a peripheral portion of the substrate, for example, the emission detection unit can detect the respective emission intensities at the central portion and the peripheral portions on the substrate with high sensitivity.

The emission detection unit is an imaging unit that images an emission spectrum indicating emission of the plasma in an in-plane direction of the substrate for each wavelength.

With this configuration, plasma emission can be continuously detected in the in-plane direction of the substrate. Furthermore, the imaging unit images an emission spectrum, and thus, light loss from the fibers to the detection unit can be made smaller than that in a configuration in which plasma light is introduced into the detection unit through fibers.

An analysis method for analyzing a chemical species generated by processing of a substrate with plasma in a processing chamber includes: detecting, for each wavelength, emission intensities of the plasma at measurement positions different from each other in a plane of the substrate; classifying data set elements formed with the emission intensities of the plasma at the respective measurement positions at each wavelength into a plurality of data aggregates at a plurality of wavelengths; and outputting representative data indicating distribution of the chemical species in the plane of the substrate, on the basis of the plurality of data aggregates.

An analysis program that is used in an analysis apparatus that analyzes a chemical species generated by processing of a substrate with plasma in a processing chamber, the analysis apparatus including an emission detection unit that detects, for each wavelength, emission intensities at measurement positions different from each other in an in-plane direction of the substrate. The analysis program causes a computer to exhibit: a function as a classification unit that classifies data set elements formed with the emission intensities at the respective measurement positions at each wavelength into a plurality of data aggregates at a plurality of wavelengths; and a function as a representative data output unit that outputs representative data indicating distribution of the chemical species in the plane of the substrate, on the basis of the plurality of data aggregates.

In a step of processing a substrate, to monitor whether the processing in a plane of the substrate is uniform, a plasma processing method for processing a substrate with plasma in a processing chamber is adopted, and the plasma processing method includes: detecting emission intensities of the plasma at measurement positions different from each other in a plane of the substrate for each wavelength under a predetermined plasma processing condition; classifying data set elements formed with the emission intensities of the plasma at the respective measurement positions at each wavelength into a plurality of data aggregates at a plurality of wavelengths; outputting representative data indicating distribution of a chemical species in the plane of the substrate, on the basis of the plurality of data aggregates; evaluating a correlation between the plasma processing condition at the time when the representative data was output and the representative data; and changing the plasma processing condition on the basis of the correlation, to make the processing in the plane of the substrate uniform.

On the other hand, in an analysis apparatus that is used in a conventional substrate processing process, a plasma emission monitor detects plasma emission, and an end point is detected on the basis of a relative change in emission of a chemical species obtained on the basis of the plasma emission. In this case, it is necessary to select a wavelength at which a relative change in the emission of the chemical species appears large in the plasma emission for each wavelength detected by the plasma emission monitor.

However, with the conventional analysis apparatus, the distribution of the chemical species above the surface of the substrate cannot be analyzed. Therefore, it is necessary to perform analysis repeatedly to select a wavelength at which a large relative change in emission appears. This takes time and effort of the user, and is uneconomical.

Therefore, to achieve the object to easily detect an end point in a substrate processing process, an analysis apparatus according to the present invention is an analysis apparatus that analyzes a chemical species in a processing chamber in which a substrate is processed with plasma, and includes: an emission detection unit that detects emission at measurement positions different from each other above a surface of the substrate; a spectral data generation unit that generates, for each of the measurement positions, spectral data indicating emission intensities for each wavelength as detected by the emission detection unit; a principal component analysis unit that performs principal component analysis on the spectral data at each wavelength for each of the measurement positions, to calculate a principal component score of the spectral data at each of the measurement positions; and a temporal change output unit that outputs a temporal change in the principal component score obtained by the principal component analysis unit.

In this configuration, the emission detection unit detects emission at measurement positions different from each other, and the principal component analysis unit performs principal component analysis on the emission intensities of the plasma at each wavelength at each of the measurement positions, to calculate the principal component score at each of the measurement positions. Accordingly, the principal component score at each measurement position indicates the distribution of the chemical species above the surface of the substrate. Further, the temporal change output unit outputs a temporal change in the principal component score obtained by the principal component analysis unit, and thus, an end point can be easily detected on the basis of the temporal change in the principal component score.

In the temporal change in the principal component score, a point of time at which the principal component score changes in an increasing manner or in a decreasing manner is defined as an end point.

In this configuration, a point of time at which the principal component score changes in an increasing manner or in a decreasing manner is an end point, and thus, deviation of an end point at each measurement position can be grasped.

Furthermore, the principal component score can be calculated immediately after the start of the substrate processing process. This eliminates the need to perform analysis repeatedly to detect an end point. Thus, the user's trouble and the required time can be reduced, and the cost can be lowered.

An analysis method for analyzing a chemical species generated by processing of a substrate with plasma in a processing chamber includes: detecting emission of the plasma at measurement positions different from each other in an in-plane direction of the substrate; generating, for each of the measurement positions, spectral data indicating emission intensities of the plasma for each wavelength as detected; performs principal component analysis on the spectral data at each wavelength for each of the measurement positions, to calculate a principal component score of the spectral data at each of the measurement positions; and outputting a temporal change in the calculated principal component score.

An analysis program that is used in an analysis apparatus that analyzes a chemical species generated by processing of a substrate with plasma in a processing chamber, the analysis apparatus including an emission detection unit that detects emission of the plasma at measurement positions different from each other in an in-plane direction of the substrate. The analysis program causes a computer to exhibit: a function as a spectral data generation unit that generates, for each of the measurement positions, spectral data indicating emission intensities of the plasma for each wavelength as detected by the emission detection unit; a function as a principal component analysis unit that performs principal component analysis on the spectral data at each wavelength for each of the measurement positions, to calculate a principal component score of the spectral data at each of the measurement positions; and a function as a temporal change output unit that outputs a temporal change in the principal component score obtained by the principal component analysis unit.

According to the present invention designed as above, it is possible to analyze the distribution of chemical species above the surface of the substrate to be processed with plasma.

### BRIEF DESCRIPTION OF THE DRAWINGS

FIG. 1 is a schematic diagram illustrating a plasma processing apparatus and an analysis apparatus according to a first embodiment of the present invention;

FIG. 2 is a schematic diagram of an emission detection unit in the first embodiment;

FIG. 3 is a functional block diagram of an information processing device in the first embodiment;

FIG. 4 is a flowchart illustrating an analysis method for analyzing distribution of chemical species above a surface of the substrate in the first embodiment;

FIG. 5 shows graphs indicating standardized spectral data at the respective measurement positions in the first embodiment;

FIG. 6 shows a graph indicating a plurality of data aggregates after classification in the first embodiment;

FIG. 7A shows a graph obtained by extracting the data aggregates in which the emission intensity is maximum at the central portion of the substrate in the first embodiment, and FIG. 7B shows a graph obtained by extracting the data aggregates in which the emission intensity is minimum at the central portion of the substrate in the first embodiment;

FIG. 8 shows a graph indicating representative data in the first embodiment;

FIG. 9 shows a table indicating plasma processing conditions in the first embodiment;

FIG. 10 is a functional block diagram of an information processing device in a second embodiment of the present invention;

FIG. 11 is a flowchart illustrating an analysis method for detecting an end point in the second embodiment;

FIG. 12 is a conceptual diagram of principal component analysis in the second embodiment;

FIG. 13A shows a graph indicating temporal changes in a first principal component score, and FIG. 13B shows a graph indicating temporal changes in a second principal component score in the second embodiment; and

FIG. 14 is a schematic diagram illustrating an emission detection unit in another embodiment.

### DETAILED DESCRIPTION

### First Embodiment

In the description below, a first embodiment of an analysis apparatus according to the present invention will be explained with reference to the drawings. Note that, for easier understanding, any of the drawings described below is schematically drawn with some portions omitted or exaggerated as appropriate in some cases. The same components are denoted by the same reference numerals, and explanation thereof will be omitted as appropriate.

### Device Configuration of the First Embodiment

An analysis apparatus 100 in the present embodiment is used for a plasma processing apparatus P that processes a substrate W such as a wafer to be used for a semiconductor, with plasma. Specifically, the analysis apparatus 100 analyzes chemical species in a processing chamber in which the substrate W is processed with plasma. In the present embodiment, the processing of the substrate W is etching or the like, for example, but is not limited to etching and may be sputtering, ashing, surface modification, ion implantation, a film formation process, and/or the like.

In the following, each component of the plasma processing apparatus P will be first described, and then, each component of the analysis apparatus 100 will be described.

### Configuration of the Plasma Processing Apparatus

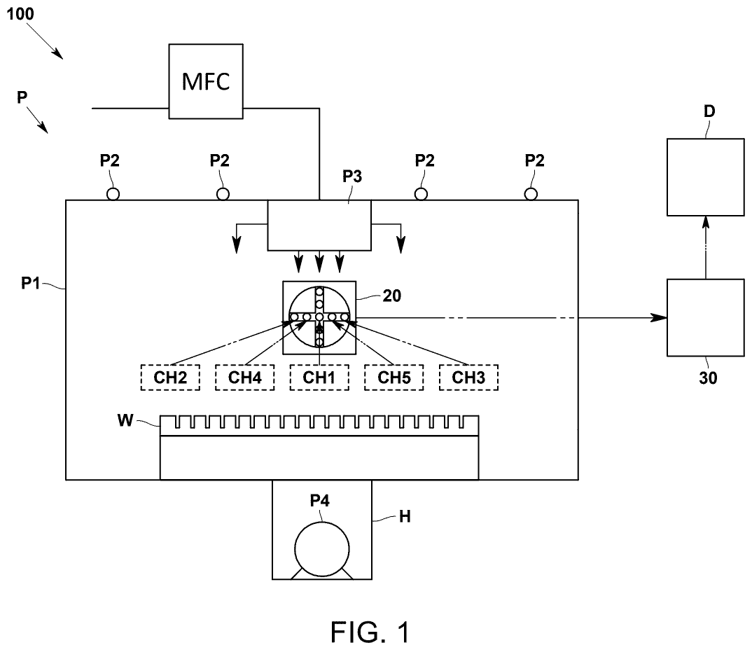

The plasma processing apparatus P generates plasma in the processing chamber, and performs processing such as etching on the surface of the substrate W with the plasma. Specifically, as illustrated in FIG. 1, the plasma processing apparatus P includes a chamber P1 that is the processing chamber in which the substrate W is processed with plasma, an antenna P2 provided outside the chamber P1, a gas supply unit P3 that supplies a material gas for etching to the chamber P1, and a gas exhaust unit P4 that exhausts the gas after etching. Note that, in the present embodiment, the plasma processing apparatus P generates inductively coupled plasma from which an induced electric field is generated in the chamber P1, but may be of a capacitively coupled type, of an electron cyclotron resonance type, one using helicon waves, and/or one using microwaves.

The chamber P1 forms an accommodation space for accommodating the substrate W. Plasma is generated in the accommodation space in the chamber P1, and the substrate W is processed with the plasma.

The antenna P2 is connected to a power supply (not shown), and voltage from the power supply is applied to the antenna P2. In the present embodiment, a high-frequency current flows into the antenna P2 when a high frequency is applied from the power supply. As a result, an induced electric field is generated in the chamber P1.

The gas supply unit P3 blows the material gas onto the entire surface of the substrate W. Specifically, the gas supply unit P3 blows the material gas toward the central portion of the substrate W, and also blows the material gas toward the peripheral portion of the substrate W. Note that, in the present embodiment, the gas supply unit P3 is connected to a flow rate adjuster such as a mass flow controller (MFC) via a flow path, for example, and the gas supply unit P3 blows the material gas having a flow rate adjusted by the flow rate adjuster, onto the substrate W.

The gas exhaust unit P4 exhausts the gas generated when etching was performed on the substrate W. Specifically, the gas exhaust unit P4 is connected to the chamber P1 via an exhaust pipe H provided immediately below the substrate W. In the present embodiment, the gas exhaust unit P4 is a turbo molecular pump or the like, for example. The gas exhaust unit P4 and/or the exhaust pipe H may be provided on both sides and/or one side of the substrate W.

### Configuration of the Analysis Apparatus

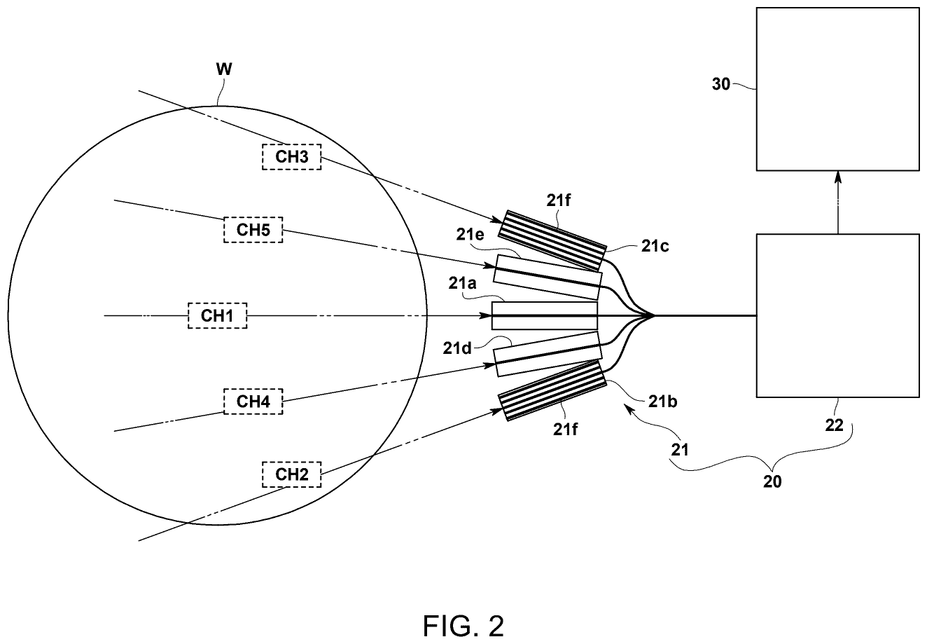

The analysis apparatus 100 analyzes the distribution of chemical species in the processing chamber by detecting emission of plasma generated in the processing chamber. Specifically, as illustrated in FIG. 2, the analysis apparatus 100 includes an emission detection unit 20 that detects the emission intensity of the plasma in the processing chamber, and an information processing device 30 that processes an output from the emission detection unit 20.

The emission detection unit 20 detects emission intensities at different measurement positions in the in-plane direction of the substrate W, for each wavelength. Specifically, the emission detection unit 20 guides emission of plasma at a plurality of measurement positions, and detects the emission intensities at the measurement positions for each wavelength on the basis of the emission of plasma guided from the measurement positions.

In the present embodiment, the measurement positions are provided from one side to the other side of the substrate W in the in-plane direction of the substrate W, and the emission detection unit 20 detects the emission intensities at the measurement positions provided from the one side to the other side of the substrate W in the in-plane direction of the substrate W. Specifically, as illustrated in FIGS. 1 and 2, the measurement positions include a first measurement position CH1 that is a measurement position in the central portion of the substrate W, a second measurement position CH2 and a third measurement position CH3 that are measurement positions in peripheral portions of the substrate W, a fourth measurement position CH4 that is a measurement position between the first measurement position CH1 and the second measurement position CH2, and a fifth measurement position CH5 that is a measurement position between the first measurement position CH1 and the third measurement position CH3. The third measurement position CH3 is a measurement position in the peripheral portion on the opposite side of the first measurement position CH1 from the second measurement position CH2. The emission detection unit 20 detects emission intensities at the measurement positions that are the first measurement position CH1 to the fifth measurement position CH5. Note that the number of measurement positions is not limited to five, and is only required to be two or larger.

In the present embodiment, the emission detection unit 20 includes a plurality of light guide units 21 that guide emission of plasma at different measurement positions via fibers 21f, and a detection unit 22 that detects the emission intensity of plasma at each measurement position on the basis of light guided by the plurality of light guide units 21.

Each light guide unit 21 is formed with one or a plurality of fibers 21f that guide emission of plasma, and guides emission at a measurement position through the fiber(s) 21f. Specifically, the fibers 21f each have a light guiding direction of guiding emission of plasma toward the measurement position, and guide emission of plasma in the light guiding direction. Note that the light guiding directions of the fibers 21f in the same light guide unit 21 are the same. The fibers 21f of the present embodiment are bundled fibers or the like.

In the present embodiment, the light guide units 21 guide emission of plasma at the respective measurement positions. The light guide units 21 have light guiding directions different from one another with respect to the in-plane direction of the substrate W, and each light guiding direction is designed for guiding emission of plasma at each of the measurement positions. With this arrangement, the light guide units 21 two-dimensionally guide emission of plasma above the surface of the substrate W.

Specifically, the plurality of light guide units 21 includes a first light guide unit 21a having a light guiding direction extending through the first measurement position CH1, a second light guide unit 21b having a light guiding direction extending through the second measurement position CH2, and a third light guide unit 21c having a light guiding direction extending through the third measurement position CH3. Although the plurality of light guide units 21 further include a fourth light guide unit 21d having a light guiding direction extending through the fourth measurement position CH4 and a fifth light guide unit 21e having a light guiding direction extending through the fifth measurement position CH5 in the present embodiment, the number of the light guide units 21 is only required to be at least two or larger.

In the present embodiment, the number of fibers 21f in at least one light guide unit 21 among the plurality of light guide units 21 is different from the number of fibers 21f in the other light guide units 21. Specifically, the numbers of fibers 21f in the light guide units 21 are set depending on the emission intensities of plasma at the plurality of measurement positions. For example, in a case where the emission intensity at the second measurement position CH2 and/or the third measurement position CH3 is lower than that at the first measurement position CH1, the number of fibers 21f in a light guide unit 21 having a light guiding direction extending through a peripheral portion of the substrate W is larger than the number of fibers 21f in the light guide unit 21 having the light guiding direction extending through the central portion of the substrate W. With this arrangement, emission at the peripheral portions of the substrate W can be guided with high sensitivity.

The detection unit 22 detects the emission intensity of plasma of each of light guide units 21 for each wavelength. Specifically, the detection unit 22 sequentially receives light from the plurality of light guide units 21, and detects the emission intensity at each measurement position, on the basis of the light guided by the respective light guide units 21. Note that, in the present embodiment, the detection unit 22 is a plasma emission monitor (an optical emission spectrometer; OES), for example. Note that the detection unit 22 may detect the emission intensity of plasma by detecting transmitted light that is laser light from a laser light source or the like passing through the chemical species, for example.

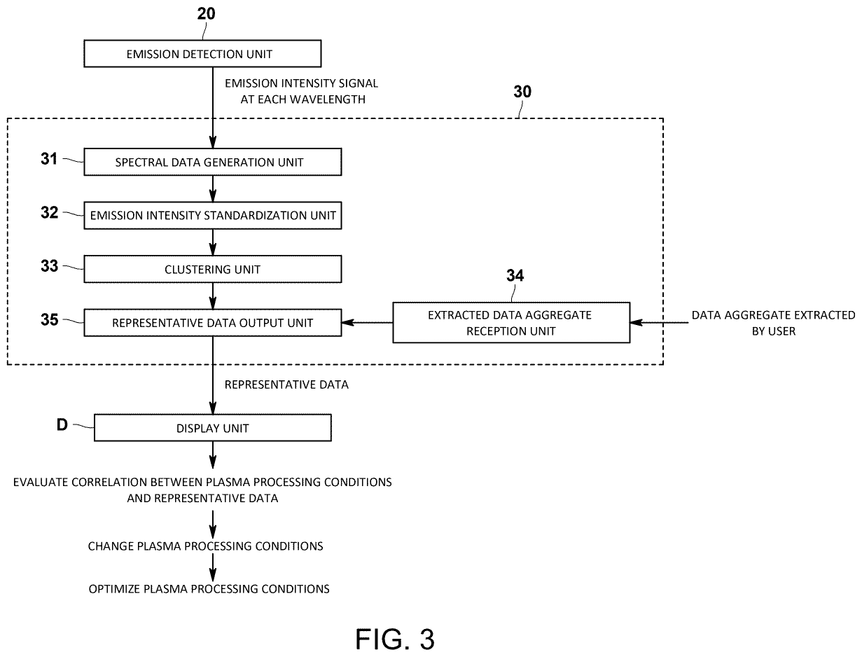

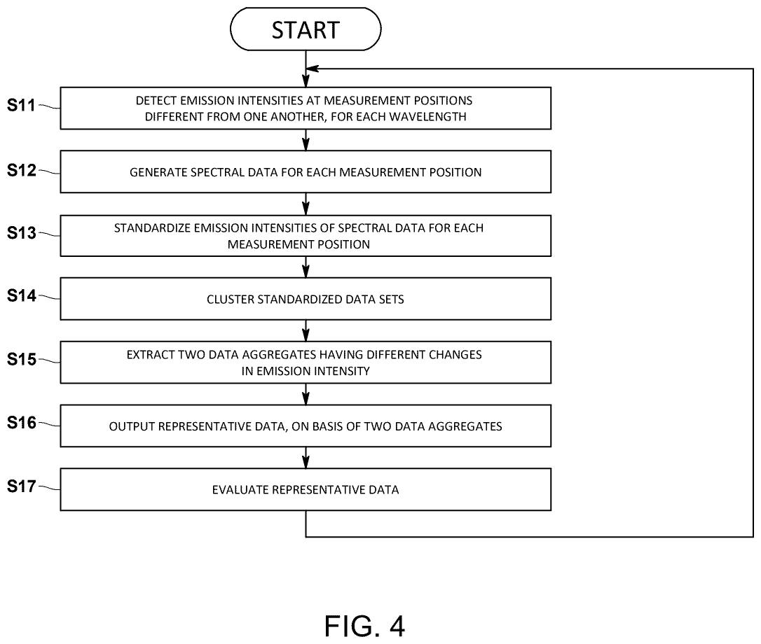

The information processing device 30 includes an analog electric circuit formed with a buffer, an amplifier, and the like, a digital electric circuit formed with a CPU, a memory, and the like, and an AD converter, a DA converter, and the like that mediate between the analog/digital electric circuits. The information processing device 30 exhibits at least a function as a spectral data generation unit 31, a function as an emission intensity standardization unit 32, a function as a classification unit 33, a function as an extracted data aggregate reception unit 34, and a function as a representative data output unit 35 as illustrated in FIG. 3, as the CPU and its peripheral devices cooperate with each other in accordance with a predetermined program stored in a predetermined area in the memory. In the following, an analysis method for analyzing the distribution of chemical species in the plane of the substrate W will be described with reference to FIGS. 3 to 8, in conjunction with a description of the functions of the respective components of the information processing device 30.

First, the gas supply unit P3 supplies the material gas to the processing space in the chamber P1. Voltage is then applied to the antenna P2 to cause a high-frequency current to flow into the antenna P2, so that plasma is generated in the chamber P1. Thus, the substrate W is processed with plasma.

Next, the emission detection unit 20 detects the emission intensities of the plasma at different measurement positions in the in-plane direction of the substrate W (S11). Specifically, the plurality of light guide units 21 guides emission of the plasma in the light guiding directions different from one another in the plane of the substrate W, and the detection unit 22 detects the emission intensity at each measurement position for each wavelength, on the basis of the emission of each of the light guide units 21.

The spectral data generation unit 31 generates spectral data indicating the emission intensity for each wavelength as detected by the emission detection unit 20. Specifically, the spectral data generation unit 31 acquires the emission intensities at the respective measurement positions for each wavelength from the detection unit 22, and generates spectral data at each measurement position (S12). In the present embodiment, the spectral data indicate the emission intensities of the plasma for all wavelengths as detected by the detection unit 22.

Next, the emission intensity standardization unit 32 standardizes the emission intensities at the respective measurement positions for each wavelength (S13). Specifically, the emission intensity standardization unit 32 acquires the spectral data related to the respective measurement positions from the spectral data generation unit 31, and standardizes the emission intensity at each measurement position for each wavelength over the entire wavelengths shown in the spectral data.

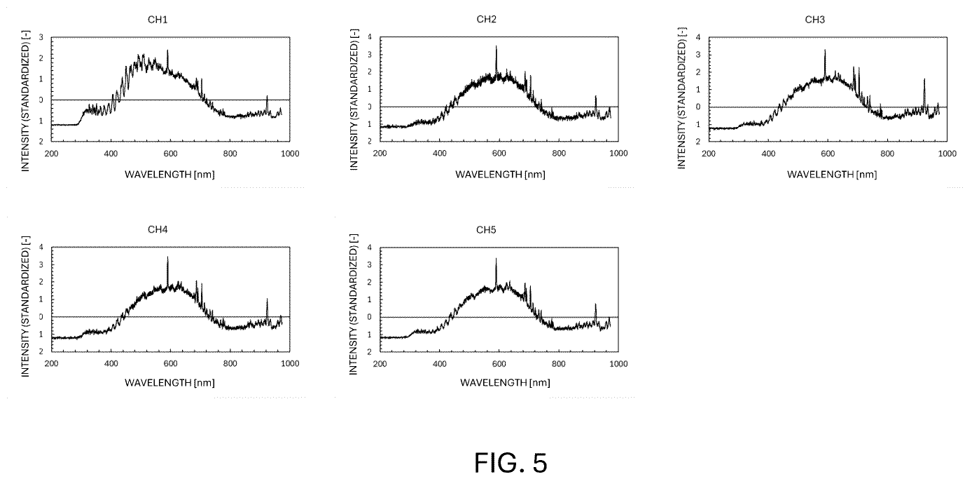

FIG. 5 shows spectral data in which the vertical axis indicates the emission intensity after standardization and the horizontal axis indicates wavelength, and, as illustrated in FIG. 5, the spectral data is standardized for each of the measurement positions CH1 to CH5. As a result, as illustrated in FIG. 5, in the spectral data after the standardization, differences in emission intensity at the measurement positions are substantially uniform. Note that the technique for standardizing emission intensities herein may be a technique by which the emission intensities at each measurement position are processed on the basis of the average value and the variance of the emission intensities, for example.

The classification unit 33 classifies data set elements formed with the emission intensities at the respective measurement positions at the respective wavelengths into a plurality of data aggregates at a plurality of wavelengths (S14). A data set element indicates the relationship between the measurement position and the emission intensity at the same predetermined wavelength. In the present embodiment, data set elements exist for each wavelength, and the data set elements at all wavelengths in the spectral data constitute data sets.

In the present embodiment, the classification unit 33 classifies the data sets into a plurality of data aggregates, using the standardized emission intensities. Specifically, the classification unit 33 sets a representative emission intensity representing each data aggregate in each of the data aggregates, and classifies the data sets into the plurality of data aggregates on the basis of the representative emission intensities in the respective data aggregates. In the present embodiment, the representative emission intensities are the average emission intensities set at the respective measurement positions, and the average emission intensity at each measurement position is set in each of the data aggregates. Note that, in the present embodiment, the classification unit 33 classifies the data sets into a plurality of data aggregates, using k-means, for example. However, it may classify the data sets into a plurality of data aggregates by some other technique such as cluster analysis and/or a self-organizing map.

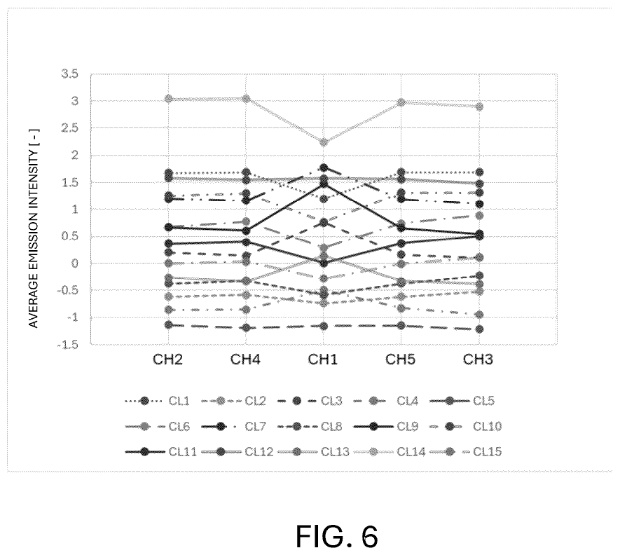

In the present embodiment, the data aggregates are different from each other in the waveform pattern formed with the average emission intensity at each of the measurement positions. Specifically, as illustrated in FIG. 6, the data aggregates have any of waveform patterns CL1 to CL15. Note that, in FIG. 6, the vertical axis indicates average emission intensity, and the horizontal axis indicates the respective measurement positions.

More specifically, the classification unit 33 compares the waveform patterns of the data set elements at a predetermined wavelength with the waveforms indicating the respective data aggregates. The classification unit 33 then classifies the data set elements at the predetermined wavelength into the data aggregate having the most approximate waveform pattern among the data aggregates. Likewise, the classification unit 33 classifies the data set elements at all the wavelengths shown in the spectral data into data aggregates having the most approximate waveform patterns. Note that a data aggregate having the most approximate waveform pattern herein refers to a data aggregate having the smallest difference between the waveform pattern of the data set elements at the predetermined wavelength and the waveform pattern of the data aggregate, for example.

As the classification unit 33 classifies the data sets, the data set elements at all the wavelengths shown in the spectral data are classified into any of a plurality of data aggregates, as illustrated in FIG. 6. The data aggregates into which the data sets have been classified are displayed on a display unit D such as a display. The waveform patterns of the data set elements classified into the same data aggregate are approximate to one another. Although the number of data aggregates is 15 in FIG. 6, it is only required to be two or larger.

As illustrated in FIG. 6, the waveform patterns of the data aggregates are different from one another. Specifically, among the plurality of data aggregates, a data aggregate indicating a chemical species contributing to a reaction, such as an etchant, for example, indicates a waveform pattern in which the emission intensity is minimized at the first measurement position CH1, which is the central portion of the substrate W. On the other hand, among the plurality of data aggregates, a data aggregate indicating a behavior opposite to that of a chemical species contributing to a reaction, such as a by-product, for example, indicates a waveform pattern in which the emission intensity is maximized at the first measurement position CH1, which is the central portion of the substrate W.

Next, the user extracts two data aggregates having different waveform patterns from each other among the plurality of data aggregates into which the data set elements have been classified (S15). Specifically, the waveform pattern of a chemical species contributing to a reaction, such as an etchant, for example, and the waveform pattern of a reaction product such as a by-product, for example, are opposite to each other. Accordingly, it is possible to analyze the distribution of the chemical species at each measurement position by extracting two data aggregates that are opposite to each other. In view of this, the user extracts, from the data aggregates, the data aggregate in which the emission intensity is maximum at the central portion of the substrate W, and the data aggregate in which the emission intensity is minimum at the central portion of the substrate W.

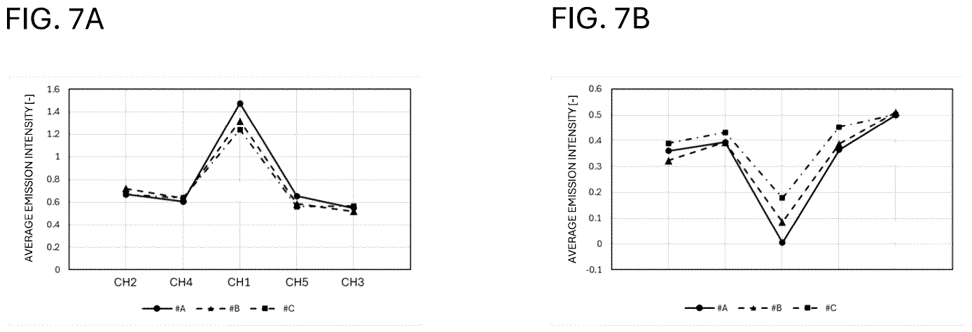

FIGS. 7A and 7B show graphs in which the vertical axis indicates average emission intensity and the horizontal axis indicates the respective measurement positions, FIG. 7A shows the data aggregate in which the emission intensity is maximum at the central portion of the substrate W, and FIG. 7B shows the data aggregate in which the emission intensity is minimum at the central portion of the substrate W. Note that, by the plasma processing method according to the present embodiment, to uniformly process the substrate W, the substrate is first processed at a predetermined plasma output, and plasma processing is performed on the substrate, with the plasma processing conditions being changed. Therefore, in FIGS. 7A and 7B, #A represents the data aggregate extracted under the first plasma processing conditions, #B represents the data aggregate extracted under the second plasma processing conditions, and #C represents the data aggregate extracted under the third plasma processing conditions. Note that the number of times the plasma processing conditions are changed is not limited to three. The user extracts the data aggregate (see FIG. 7A) having the largest local maximum value among the data aggregates in which the emission intensity is maximum at the central portion of the substrate W and the data aggregate (see FIG. 7B) having the smallest local minimum value among the data aggregates in which the emission intensity is minimum at the central portion of the substrate W. The extracted two data aggregates are then received by the extracted data aggregate reception unit 34. Although the user extracts the data aggregates in the present embodiment, a computer may extract the data aggregates.

The representative data output unit 35 outputs representative data indicating the distribution of chemical species in the plane of the substrate W, on the basis of a plurality of data aggregates. Specifically, the representative data output unit 35 calculates the representative data on the basis of the two data aggregates received by the extracted data aggregate reception unit 34, and outputs the representative data to the display unit D such as a display, for example (S16).

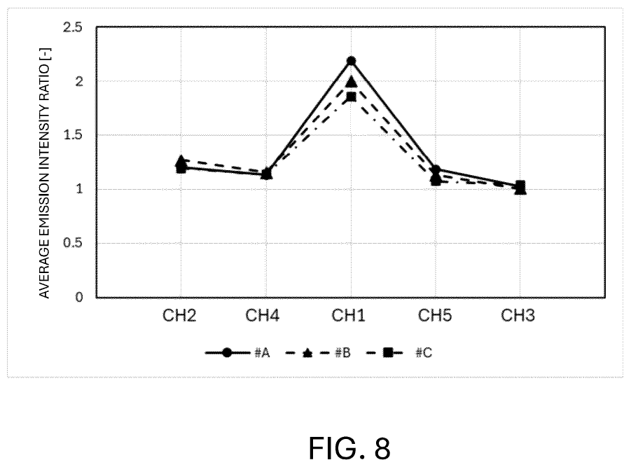

In the present embodiment, the representative data output unit 35 calculates the ratio between the representative emission intensities in the two data aggregates. More specifically, the representative data output unit 35 calculates the ratio between the average emission intensities of the two data aggregates for each measurement position, and sets the ratio between the average emission intensities of the two data aggregates as the representative data for the measurement position, as illustrated in FIG. 8. Thus, it is possible to analyze the distribution of the chemical species ratio at each measurement position, by calculating the emission intensity ratio at each measurement position in the two data aggregates that are opposite to each other.

Next, the user or the computer evaluates the correlation between the plasma processing conditions and the representative data at the time of the outputting of the representative data (S18). The user or the computer may change the plasma processing conditions on the basis of the representative data so that the substrate W is uniformly processed, for example. The user or the computer may change the plasma processing conditions every time representative data is output, or may change the plasma processing conditions on the basis of the representative data obtained during a predetermined period or at a predetermined timing. Alternatively, the user or the computer may change the plasma processing conditions on the basis of the representative data obtained during the previous plasma processing for each substrate W.

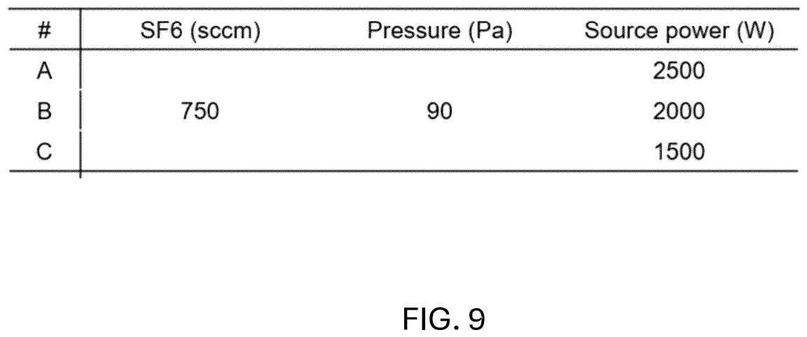

In the present embodiment, as shown in FIG. 9, in the plurality of plasma processing conditions #A to #C, the gas flow rate, the pressure, and the measurement time are the same, but the power is changed. Further, because the shape of the representative data changed depending on the change in the plasma processing conditions, it is apparent that there is a correlation between the change in the plasma processing conditions and the change in the shape of the representative data.

Specifically, as illustrated in FIGS. 8 and 9, when the power is changed so as to be smaller among the plasma processing conditions #A to #C, the ratio of the average emission intensity at the first measurement position CH1 gradually decreases with the change in the power, and the shape of the representative data changes from a convex shape to a flatter shape at the first measurement position CH1.

Therefore, in the step of processing the substrate W, controlling the plasma processing conditions so as to uniformly process the substrate W is complicated. However, it is estimated that, by monitoring the correlation between the change of the plasma processing conditions and the change in the shape of the representative data, it is possible to optimize the plasma processing conditions by a simpler method, compared with a complicated and troublesome conventional method that involves monitoring spectral data.

Although the power is changed among the plasma processing conditions in FIG. 9, a plasma processing condition other than the power, such as the gas flow rate ratio, the pressure, the wafer temperature, or the measurement time, may be changed in a similar manner. By monitoring the correlation between the change in the plasma processing conditions and the change in the shape of the representative data, it is possible to easily observe the pressure dependence in the in-plane direction of the substrate, the gas flow rate dependence, the temperature dependence, or the like in the step of processing the substrate W.

As described above, the representative data can be handled as a parameter correlated with the processing of the substrate W, such as an etching rate, for example. Thus, by controlling the plasma output using the representative data, it is possible to achieve uniformity in the processing in the in-plane direction of the substrate W in the step of processing the substrate W.

### Effects of the First Embodiment

In the analysis apparatus 100 according to the first embodiment, the emission detection unit 20 detects emission at different measurement positions, and thus, it is possible to detect emission intensities in the entire plane of the substrate W. The representative data output unit 35 then calculates the ratio between the emission intensities in two data aggregates having different waveform patterns of emission intensities at each measurement position, and outputs the ratio as the representative data. Thus, by monitoring the representative data, it is possible to analyze the distribution of the chemical species ratio above the surface of the substrate.

In addition to that, the classification unit 33 classifies the data set elements formed with emission intensities at the respective positions in the in-plane direction of the substrate W at each wavelength into a plurality of data aggregates at a plurality of wavelengths. Thus, all the wavelengths of the emission intensities detected by the emission detection unit 20 are reflected in the plurality of data aggregates after the classification. Accordingly, although only some of the wavelengths detected by the emission detection unit 20 are used in conventional cases, the classification unit 33 according to the present embodiment uses all the wavelengths of the emission intensities detected by the emission detection unit 20. Thus, it is possible to analyze the distribution of the chemical species ratio in the plane of the substrate W, regardless of the database and/or the ability of the user.

### Modifications of the First Embodiment

Note that the present invention is not limited to the first embodiment.

In the above embodiment, a representative emission intensity is the ratio between the average emission intensities in two data aggregates at each measurement position. However, a configuration for achieving a higher analysis accuracy than that with a configuration in which representative data is calculated from one data aggregate is not limited to this. For example, a representative emission intensity may be the ratio between the maximum values and the minimum values in two data aggregates.

In the above embodiment, the representative data output unit 35 calculates representative data on the basis of two data aggregates different from each other, but may calculate representative data on the basis of three or more data aggregates.

In the above embodiment, the data aggregates to be extracted have the extreme values at the central portion of the substrate W. However, a configuration for achieving a higher analysis accuracy than that with a configuration in which representative data is calculated from one data aggregate is not limited to this. For example, in a case where an output of plasma is sequentially changed in the step of processing the substrate W, the user and/or the computer may extract a data aggregate in which the emission intensity at each measurement position is sequentially changed depending on the output of the plasma.

In the above embodiment, the number of fibers 21f in at least one light guide unit 21 among the plurality of light guide units 21 is different from the number of fibers 21f in the other light guide units 21. However, in a case where the emission intensity of plasma is substantially the same at the central portion and the peripheral portions of the substrate W, for example, the number of fibers 21f in the plurality of light guide units 21 may be the same.

In the above embodiment, the analysis apparatus 100 includes the spectral data generation unit 31 and the emission intensity standardization unit 32. However, to check the distribution of the chemical species in the plane of the substrate on the basis of a plurality of data aggregates by classifying data set elements into the plurality of data aggregates at a plurality of wavelengths, the analysis apparatus 100 is only required to include at least the emission detection unit 20 and the classification unit 33.

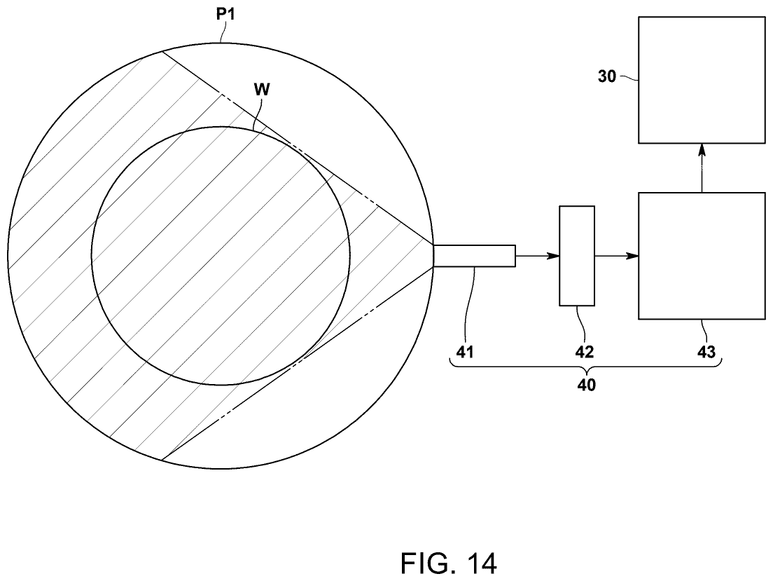

In the above embodiment, the emission detection unit 20 discretely detects emission of plasma at different measurement positions via the fibers 21f, but may continuously detect emission of plasma in the in-plane direction of the substrate W. For example, as illustrated in FIG. 14, the emission detection unit 20 may be an imaging unit 40 that images an emission spectrum indicating the emission for each wavelength of plasma in the in-plane direction of the substrate W.

Specifically, the imaging unit 40 continuously detects the emission of plasma in the in-plane direction of the substrate W, to scan and image the emission spectrum in the in-plane direction of the substrate W. More specifically, as illustrated in FIG. 14, the imaging unit 40 is a hyperspectral camera in which a condenser lens 41, a spectrometer 42, and a light detection unit 43 are combined. The hyperspectral camera is attached to the chamber P1, and captures an emission spectrum by scanning the entire plane in the substrate W. Note that the hyperspectral camera may capture part of the plane in the substrate W. Also, the hyperspectral camera may two-dimensionally capture an image of the entire in-plane emission in the substrate W, without scanning any emission spectrum.

The condenser lens 41 collects plasma light in the in-plane direction of the substrate W. Specifically, the condenser lens 41 has a view angle at which plasma light can be collected from one side to the other side in the in-plane direction of the substrate W.

The spectrometer 42 divides the plasma light collected by the condenser lens 41, by the wavelength. Specifically, the spectrometer 42 is a grating that has wavelength resolution and divides, by the wavelength, the plasma light condensed by the condenser lens 41.

The light detection unit 43 detects the light at each wavelength of the plasma as emitted from the spectrometer 42. Specifically, the light detection unit 43 may be a CMOS image sensor, a CCD image sensor, or the like in which light receiving elements are arranged in an array.

With this configuration, plasma emission can be continuously detected in the in-plane direction of the substrate W. In addition to that, the imaging unit 40 images the emission spectrum. Thus, light loss from the fibers 21f to the detection unit 22 can be reduced as compared with that in a configuration in which plasma light is introduced into the detection unit 22 by the fibers 21f.

Although the imaging unit 40 performs imaging unidirectionally in the in-plane direction of the substrate W in FIG. 14, a plurality of imaging units 40 may be provided above the substrate W, and each imaging unit 40 may image an emission spectrum in each of different in-plane directions of the substrate W.

In a case where the plurality of imaging units 40 images an emission spectrum in each of different in-plane directions of the substrate W, the distribution of concentration of the target chemical species above the substrate W can be estimated by the method described below.

First, a reference emission spectrum (or an emission intensity ratio) serving as a reference for the target chemical species is acquired. Specifically, an emission spectrum of the chemical species is detected at a predetermined position in the chamber P1, and the emission spectrum is set as the reference emission spectrum.

Next, the plurality of imaging units 40 images an emission spectrum in different in-plane directions of the substrate W. Specifically, the plurality of imaging units 40 images an emission spectrum in each of the mutually intersecting in-plane directions of the substrate W.

Next, the user or the computer assumes a concentration distribution of the target chemical species on the basis of a plurality of emission spectra obtained from the plurality of imaging units 40. Specifically, the concentration distribution of the target chemical species is assumed using the following Mathematical Expression 1.

$$C ( x , y ) = {\sum }_{i - 1}^{N} {A}_{i} exp \{ - \frac{{( x - {x}_{i} )}^{2}}{2 {σ}_{xi}^{2}} - \frac{{( y - {y}_{i} )}^{2}}{2 {σ}_{yi}^{2}} \} \qquad [ Mathematical Expression 1 ]$$

Here, C (x, y) represents the chemical species concentration distribution, Aᵢ represents the Gaussian peak center concentration, xᵢ represents the Gaussian center position in the x direction, σₓᵢ represents the Gaussian dispersion in the x direction, yᵢ represents the Gaussian center position in the y direction, and σ_{yi} represents the Gaussian dispersion in the y direction.

Next, the computer calculates the value of integral of the concentration in each optical path, on the basis of the assumed concentration distribution. A calculated value of the spectrum in each optical path is then calculated, on the basis of the value of integral and the reference emission spectrum acquired beforehand. The calculated value of the spectrum is compared with the emission spectrum measured by the imaging unit 40, the squared error thereof is integrated for all the optical paths, and fitting is performed on each of the parameters in Mathematical Expression 1 so that the squared error is minimized. Thus, a candidate for the concentration distribution of the target chemical species can be obtained. However, this is a relative concentration distribution based on the integrated concentration of the optical path from which the reference emission spectrum has been acquired, and does not present the absolute value of concentration.

### Second Embodiment

An analysis apparatus according to a second embodiment is now described, with reference to the drawings. Note that, for easier understanding, any of the drawings described below is schematically drawn with some portions omitted or exaggerated as appropriate in some cases. The same components are denoted by the same reference numerals, and explanation thereof will be omitted as appropriate.

### Device Configuration of the Second Embodiment

An analysis apparatus 100 according to the second embodiment differs partially in the configuration of the information processing device 30. Therefore, this difference and its peripheral components will be described below, and explanation of the other components will be omitted.

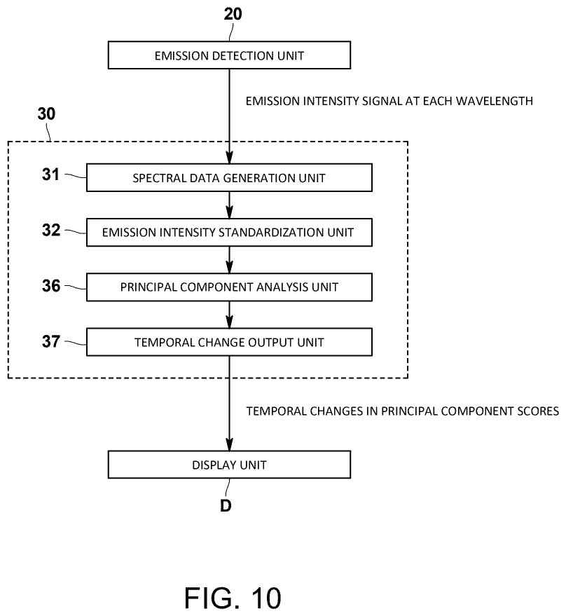

As illustrated in FIG. 10, an information processing device 30 of the second embodiment differs from the information processing device 30 of the first embodiment in components that exhibit a function as a principal component analysis unit 36 and a function as a temporal change output unit 37.

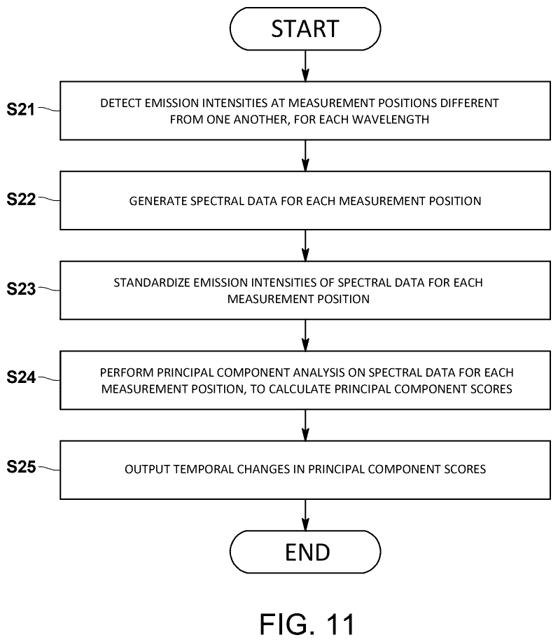

The analysis apparatus 100 of the second embodiment analyzes an end point of each measurement position in the plane of the substrate W. In the following, an analysis method for detecting an end point will be described with reference to FIGS. 10 to 13A and 13B, in conjunction with a description of the functions of the respective components of the information processing device 30 of the second embodiment. Note that, in FIGS. 11, S21 to S23 are the same as S11 to S13 of the first embodiment, and therefore, explanation of them is omitted herein.

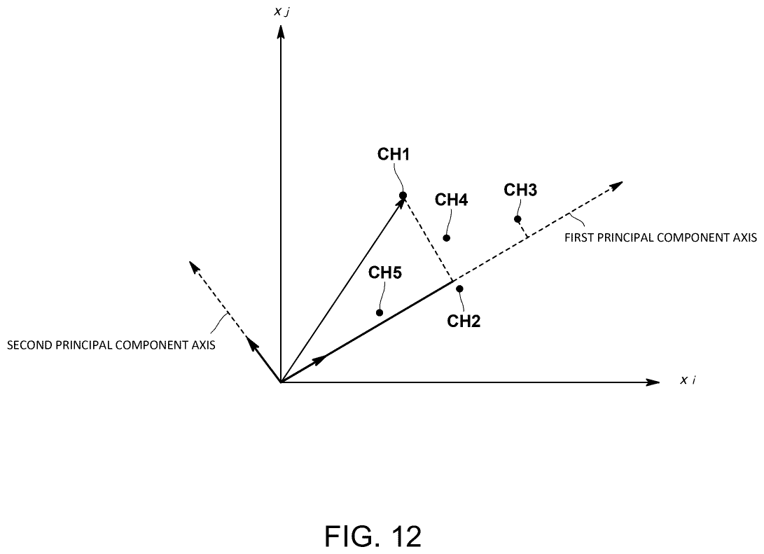

The principal component analysis unit 36 performs principal component analysis on the spectral data for each of the measurement positions at each wavelength, and calculates a principal component score of the spectral data at each measurement position (S24). FIG. 12 shows a graph in which the vertical axis and the horizontal axis indicate wavelengths different from each other, and spectral data at each measurement position in the wavelengths of the vertical axis and the horizontal axis are plotted. Specifically, as shown in FIG. 12, spectral data at a plurality of measurement positions is plotted in a virtual dimensional space corresponding to the number of wavelengths indicated in the spectral data. The principal component analysis unit 36 then performs principal component analysis on the spectral data at the plurality of measurement positions plotted in the virtual dimensional space.

More specifically, as shown in FIG. 12, with respect to spectral data at the plurality of measurement positions, the axis having the largest dispersion is defined as a first principal component axis e1, and the axis having the second largest dispersion is defined as a second principal component axis e2. The principal component analysis unit 36 then calculates a first principal component score for each measurement position, the first principal component score being the inner product of the spectral data and the directional vector of the first principal component axis e1. The principal component analysis unit 36 also calculates a second principal component score for each measurement position, the second principal component score being the inner product of the spectral data and the directional vector of the second principal component axis e2. Note that, in the present embodiment, the principal component analysis unit 36 calculates the first principal component score and/or the second principal component score in the process of processing the substrate W.

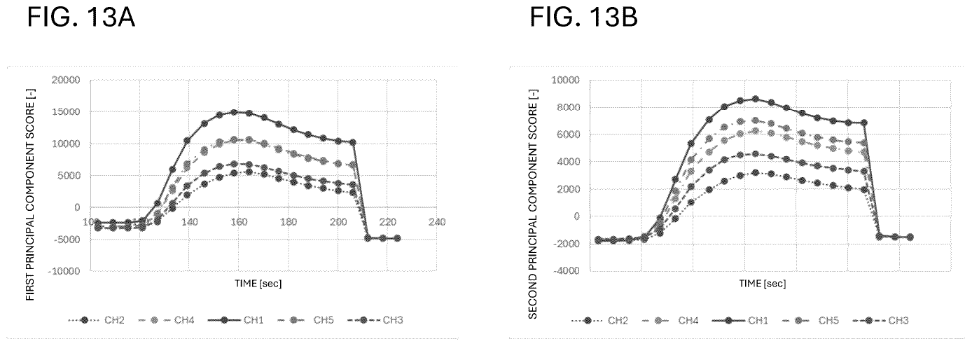

The temporal change output unit 37 outputs temporal changes in the principal component scores obtained by the principal component analysis unit 36 (S25). Specifically, as illustrated in FIGS. 13A and 13B, the temporal change output unit 37 outputs temporal changes in the principal component scores to the display unit D for each measurement position. Note that, as illustrated in FIGS. 13A and 13B, the temporal change output unit 37 outputs the temporal change in the first principal component score and the temporal change in the second principal component score for each measurement position, but may output the temporal change in one of the principal component scores.

Here, as illustrated in FIGS. 13A and 13B, in the temporal change in a principal component score, a point of time at which the principal component score changes in an increasing manner is an end point. Specifically, in the temporal change in a principal component score for each measurement position, a point of time at which the principal component score changes in an increasing manner appears at each measurement position. Because of this, an end point in the plane of the substrate W can be seen at each measurement position. Accordingly, even in a case where end points differ between the central portion and a peripheral portion of the substrate W, a point of time at which a principal component score changes in an increasing manner appears at each measurement position, and thus, it is possible to grasp the deviation of an end point for each measurement position.

### Effects of the Second Embodiment

In the analysis apparatus 100 according to the second embodiment, the emission detection unit 20 detects emission at different measurement positions, and the principal component analysis unit 36 performs principal component analysis on the spectral data at each of the measurement positions, to calculate the principal component score of the spectral data at each measurement position. Accordingly, the principal component score at each measurement position indicates the distribution of gas in an in-plane direction of the substrate. Further, the temporal change output unit 37 outputs temporal changes in the principal component scores obtained by the principal component analysis unit 36, and thus, end points can be easily detected on the basis of the temporal changes in the principal component scores.

### Modifications of the Second Embodiment

Note that the present invention is not limited to the second embodiment.

In the above embodiment, in a temporal change in a principal component score, a point of time at which the principal component score changes in an increasing manner is an end point, but a point of time at which the principal component score changes in a decreasing manner may be an end point.

In addition to that, various modifications and combinations of the embodiments may be made without departing from the scope of the present invention.

According to the present invention, it is possible to analyze the distribution of chemical species above the surface of the substrate to be processed with plasma.

### REFERENCE SIGNS LIST

100 analysis apparatus
20 emission detection unit
21 light guide unit
21f fiber
22 detection unit
30 information processing device
31 spectral data generation unit
32 emission intensity standardization unit
33 classification unit
34 extracted data aggregate reception unit
35 representative data output unit
36 principal component analysis unit
37 temporal change output unit
P plasma processing apparatus
P1 chamber
P2 antenna
P3 gas supply unit
P4 gas exhaust unit

What is claimed is:

1. An analysis apparatus that analyzes a chemical species generated by processing of a substrate with plasma in a processing chamber, the analysis apparatus comprising:
an emission detection unit that detects, for each wavelength, emission intensities of the plasma at measurement positions at least partially different from each other above a surface of the substrate;
a classification unit that classifies data set elements formed with the emission intensities of the plasma at the respective measurement positions at each wavelength into a plurality of data aggregates at a plurality of wavelengths; and
a representative data output unit that outputs representative data indicating distribution of the chemical species above the surface of the substrate, on a basis of the plurality of data aggregates.

2. The analysis apparatus according to claim 1, wherein
the data aggregates are different from each other in a waveform pattern formed with the emission intensities of the plasma at each of the measurement positions, and
the representative data output unit calculates the representative data on a basis of two or more of the data aggregates different from each other.

3. The analysis apparatus according to claim 2, wherein
two of the data aggregates each have a representative emission intensity that is a plasma emission intensity representing each corresponding data aggregate, and
the representative data is a ratio between the representative emission intensities in the two of the data aggregates.

4. The analysis apparatus according to claim 1, wherein the representative data output unit outputs the representative data, on a basis of a data aggregate in which the emission intensity of the plasma at a central portion of the substrate is maximum, and a data aggregate in which the emission intensity of the plasma at the central portion of the substrate is minimum.

5. The analysis apparatus according to claim 1, further comprising an emission intensity standardization unit that standardizes emission intensities of the plasma at the respective wavelengths for each of the measurement positions,
wherein the classification unit classifies the data set elements into a plurality of data aggregates at a plurality of wavelengths, using the standardized emission intensities of the plasma.

6. The analysis apparatus according to claim 1, wherein
the emission detection unit includes:
a plurality of light guide units, each of which is formed with one or a plurality of fibers, the light guide units guiding emission of the plasma at different positions above the surface of the substrate via the fibers; and
a detection unit that detects the emission intensities corresponding to the emission of the plasma guided by the light guide units for each wavelength, and
the number of the fibers in at least one of the light guide units is different from the number of the fibers in other ones of the light guide units.

7. The analysis apparatus according to claim 1, wherein the emission detection unit is an imaging unit that images an emission spectrum indicating emission of the plasma on the surface of the substrate for each wavelength.

8. An analysis method for analyzing emission intensity of a chemical species generated by processing of a substrate with plasma in a processing chamber, the analysis method comprising:
detecting, for each wavelength, emission intensities of the plasma at measurement positions different from each other above a surface of the substrate;
classifying data set elements formed with the emission intensities of the plasma at the respective measurement positions at each wavelength into a plurality of data aggregates at a plurality of wavelengths; and
outputting representative data indicating distribution of the chemical species above the surface of the substrate, on a basis of the plurality of data aggregates.

9. A computer-readable medium including an analysis program that is used in an analysis apparatus that analyzes a chemical species generated by processing of a substrate with plasma in a processing chamber,
the analysis apparatus including an emission detection unit that detects, for each wavelength, emission intensities of the plasma at measurement positions different from each other above a surface of the substrate,
the analysis program causing a computer to exhibit:
a function as a classification unit that classifies data set elements formed with the emission intensities of the plasma at the respective measurement positions at each wavelength into a plurality of data aggregates at a plurality of wavelengths; and
a function as a representative data output unit that outputs representative data indicating distribution of the chemical species above the surface of the substrate, on a basis of the plurality of data aggregates.

10. A plasma processing method for processing a substrate with plasma in a processing chamber, the plasma processing method comprising:
detecting emission intensities of the plasma at measurement positions different from each other above a surface of the substrate for each wavelength under a predetermined plasma processing condition;
classifying data set elements formed with the emission intensities of the plasma at the respective measurement positions at each wavelength into a plurality of data aggregates at a plurality of wavelengths;
outputting representative data indicating distribution of a chemical species above the surface of the substrate, on a basis of the plurality of data aggregates;
evaluating a correlation between the plasma processing condition at a time when the representative data is output and the representative data; and
changing the plasma processing condition on a basis of the correlation, to make the processing in a plane of the substrate uniform.

11. An analysis apparatus that analyzes a chemical species generated by processing of a substrate with plasma in a processing chamber, the analysis apparatus comprising:
an emission detection unit that detects emission of the plasma at measurement positions different from each other above a surface of the substrate;
a spectral data generation unit that generates, for each of the measurement positions, spectral data indicating emission intensities of the plasma for each wavelength as detected by the emission detection unit;
a principal component analysis unit that performs principal component analysis on the spectral data at each wavelength for each of the measurement positions, to calculate a principal component score of the spectral data at each of the measurement positions; and
a temporal change output unit that outputs a temporal change in the principal component score obtained by the principal component analysis unit.

12. The analysis apparatus according to claim 11, wherein, in the temporal change in the principal component score, a point of time at which the principal component score changes in an increasing manner or in a decreasing manner is defined as an end point.

13. An analysis method for analyzing a chemical species generated by processing of a substrate with plasma in a processing chamber, the analysis method comprising:
detecting emission of the plasma at measurement positions different from each other above a surface of the substrate;
generating, for each of the measurement positions, spectral data indicating emission intensities of the plasma for each wavelength as detected;
performing principal component analysis on the spectral data at each wavelength for each of the measurement positions, to calculate a principal component score of the spectral data at each of the measurement positions; and
outputting a temporal change in the calculated principal component score.

14. A computer-readable medium including an analysis program that is used in an analysis apparatus that analyzes a chemical species generated by processing of a substrate with plasma in a processing chamber,
the analysis apparatus including an emission detection unit that detects emission of the plasma at measurement positions different from each other above a surface of the substrate,
the analysis program causing a computer to exhibit:
a function as a spectral data generation unit that generates, for each of the measurement positions, spectral data indicating emission intensities of the plasma for each wavelength as detected by the emission detection unit;
a function as a principal component analysis unit that performs principal component analysis on the spectral data at each wavelength for each of the measurement positions, to calculate a principal component score of the spectral data at each of the measurement positions; and
a function as a temporal change output unit that outputs a temporal change in the principal component score obtained by the principal component analysis unit.
